(19) United States
(12) Patent Application Publication
(10) Pub. No.: US 2006/0024944 A1
(43) Pub. Date: Feb. 2, 2006

(54) Metal pad of semiconductor device and method for bonding the metal pad

(75) Inventor: Meng An Jung, Eumsung-gun (KR)

Correspondence Address: OBLON, SPIVAK, MCCLELLAND, MAIER & NEUSTADT, P.C., 1940 DUKE STREET, ALEXANDRIA, VA, 22314, US

(73) Assignee: DongbuAnam Semiconductor Inc., Kangnam-ku (KR)

(21) Appl. No.: 11/024,699

(22) Filed: Dec. 30, 2004

(30) Foreign Application Priority Data
Jul. 27, 2004 (KR) 10-2004-0058640

(51) Int. Cl. H01L 21/44

(52) U.S. Cl. 438/612; 438/617

(57) ABSTRACT

A method of bonding a metal pad of the semiconductor device including a step of forming a metal pad in a pad forming area of a chip and another pad forming area of another chip. The another chip is adjacent to the chip, and both the chip and the another chip are on a wafer. The method further includes forming a protective layer at least on the metal pad and separating the metal pad to provide separated metal pads. One of the separated metal pads is attached to the chip and another of the separated metal pads is attached to the another chip. Then, at least some of the protective layer and at least some of the one of the separated metal pads is removed to provide an exposed metal pad. A package lead line is attached to the exposed metal pad.

### BACKGROUND OF THE INVENTION

1. Field of the Invention

The present invention relates to a method of fabricating a semiconductor device, and, more particularly to a metal pad of a semiconductor device and a method for bonding the metal pad.

2. Discussion of the Related Art

The method of fabricating a semiconductor device may include a fabrication (FAB) process and a package process. The FAB process may include fabricating fine patterns on a silicon wafer so as to form a circuit. The package process may provide electricity to a wafer having fine patterns formed thereon. The package process may include dividing high quality chips (or die) to individual units. Then, the individual units may be packaged thereby protecting the chip from external mechanical, physical and chemical impacts and enabling a printed circuit board (PCB) to be mounted.

FIGS. 1A to 1C illustrate cross-sectional views showing process steps of opening and bonding metal pads of a semiconductor device. In the package process the metal pad may be categorized as either good quality or bad quality at the wafer level. Then, the opening and bonding process may be performed. The opening and bonding process may include a wafer mounting step, a sawing step individualizing each chip based on a scribe lane, and a wire bonding step bonding the individualized chips to a lead frame by using a conductive adhesive, such as epoxy resin, and connecting the metal pad of the chip and a lead of the lead frame using, for example, highly pure gold wires to establish an electric connection. The opening and bonding process may further include a molding step molding the outer surface of the chip, after the wire bonding step, with a thermo-hardening resin so as to protect the chip from physical impacts or chemical changes.

FIG. 1A illustrates a process of opening a metal pad pattern by using a photolithography process. Fine patterns (not shown) for forming chip circuits may be formed on a wafer by, for example, film fabrication, dispersion process, photolithography process, and/or etching process. A metal pad 12 may be formed on the interlayer dielectric 11 in the pad forming area of the wafer, on which the above-described fine patterns may be formed. Subsequently, in order to open the metal pad 12 for a connection with an external power source, a photoresist layer may be deposited on the entire surface, which may be selectively exposed to light and developed, thereby forming a photoresist pattern layer 14 having a pad opening area.

Thereafter, referring to FIG. 1B, the photoresist pattern layer 14 may be used as a mask to selectively etch the exposed portion of the protective layer 13, thereby forming protective layer 13a and opening the metal pad 12. The protective layer 13a is exposed after being treated with a plasma etching process. Subsequently, as shown in FIG. 1C, the sawing process in the package process is performed by individualizing the chips, connecting melted metal to the metal pad 12, using a conductive material, such as a package lead line 15, to connect the individualized chip with a set form of frame (not shown). A dotted line ‘A’ of FIG. 1B represents a scribe lane for individualizing the chips.

However, in the method of the related art, the process of exposing the metal pad is complicated and the chemicals used during the process may cause corrosion of the metal pad. Corrosion of the metal pad may also be caused by ambient air, and such corrosion may disturb the bonding process and may cause the device to be easily contaminated by external contaminants, thereby deteriorating the quality of the device, which eventually decreases the yield of the device.

### SUMMARY OF THE INVENTION

Accordingly, the present invention is directed to a metal pad of a semiconductor device and a method for bonding the metal pad that substantially obviate one or more problems due to limitations and disadvantages of the related art.

A method of bonding a metal pad of the semiconductor device may comprise forming a metal pad in a pad forming area of a chip and another pad forming area of another chip. The another chip may be adjacent to the chip, and both the chip and the another chip may be on a wafer. The method further comprises forming a protective layer at least on the metal pad and separating the metal pad to provide separated metal pads. One of the separated metal pads may be attached to the chip and another of the separated metal pads may be attached to the another chip. Then, at least some of the protective layer and at least some of the one of the separated metal pads may be removed to provide an exposed metal pad. A package lead line may be attached to the exposed metal pad.

The removing step may further include cutting at least some of the protective layer and at least some of the one of the separated metal pads so that the exposed metal pad has a slanting surface. The slope of the slanting surface may be less than or equal to about 45°.

It is to be understood that both the foregoing general description and the following detailed description of the present invention are exemplary and explanatory and are intended to provide further explanation of the invention as claimed.

### BRIEF DESCRIPTION OF THE DRAWINGS

A more complete appreciation of the present invention and many of the attended advantages thereof will be readily obtained as the present invention becomes better understood by reference to the following detailed description when considered in connection with the accompanying drawings, in which like reference characters refer to like parts throughout, wherein:

FIGS. 1A to 1C illustrate cross-sectional views of opening and bonding metal pads of a semiconductor device according to related art; and

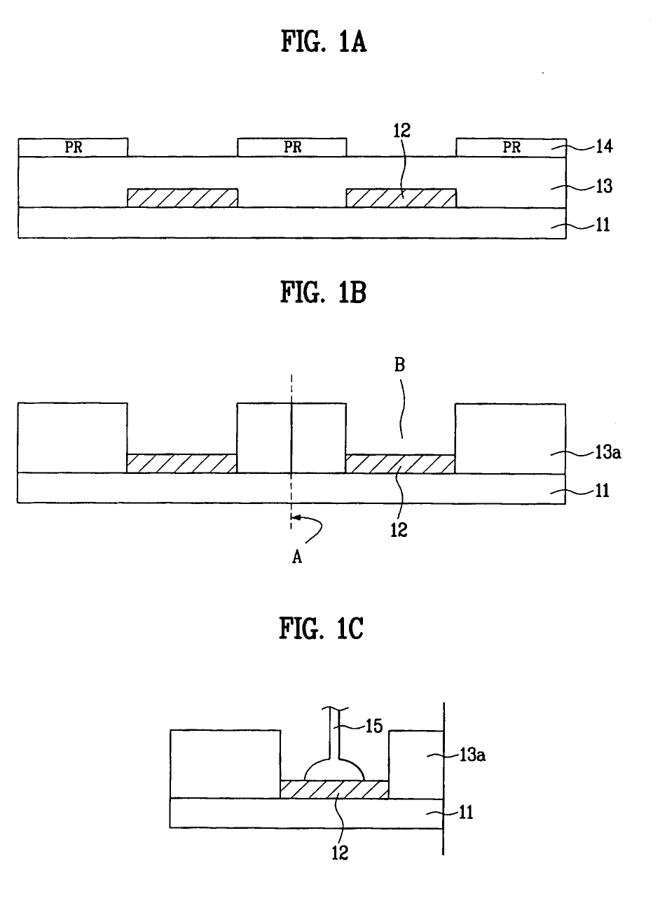

FIGS. 2A to 2C illustrate cross-sectional views of opening and bonding metal pads of a semiconductor device according to the present invention.

### DETAILED DESCRIPTION OF THE INVENTION

The present invention may to a method of fabricating a semiconductor device, and, more particularly to a metal pad of a semiconductor device and a method for bonding the metal pad.

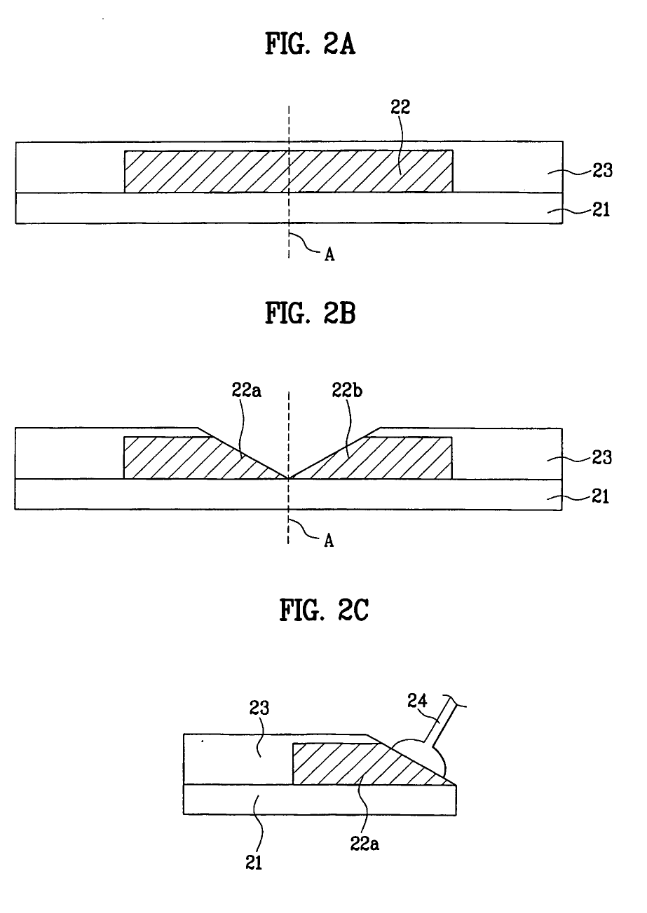

FIGS. 2A to 2C illustrate cross-sectional views of opening and bonding metal pads of a semiconductor device according to the present invention. A metal pad opening and bonding process consistent with the present invention may include a process of forming fine patterns (not shown). The process of forming fine patterns may include forming a chip circuit on a wafer by carrying out a thin film fabricating process, a dispersion process, a photolithography process, an etching process, etc. As shown in FIG. 2A, in the pad forming area of the wafer, on which the fine patterns may be formed, a metal pad 22 may be formed on the interlayer dielectric 21. In one embodiment consistent with the present invention, one pad metal may be formed in both a pad forming area of a chip and another pad forming area of another chip adjacent to the chip, wherein both the chip and the another chip are on a wafer. The protective layer 23 may be formed to cover the metal pad. The protective layer 23 may include, for example, a nitride layer, an oxide layer, or any combination thereof. The protective layer 23 may protect the devices and circuits formed on the wafer.

Then, as shown in FIG. 2B, an individualization process may be performed. The metal pad 22 may be cut into, for example, two pieces 22a and 22b based on the scribe lane ‘A’, which is used as a cutting guide during the chip individualizing process. Then, a sawing process is performed so that at least a portion of the metal pad 22a or 22b may be exposed. During the sawing process, at least a portion of the metal pad 22a or 22b, as well as at least a portion of the protective layer 23, may be removed. The sawing process may be performed starting from the scribe lane ‘A’ and the sawing angle may be set for less than or equal to about 45° from the horizontal axis. Accordingly, the exposed portion of the metal pad 22a or 22b may have a slanting surface. In one embodiment consistent with the present invention, the sawing angle can be greater than about 5° and less than about 85°. Then, a metal may be connected to the metal pad layer 22a or 22b. Then, as shown in FIG. 2C, the metal pad layer 22a may be connected to a frame (not shown) by using a conductive material, such as the package lead line 24. The package lead line may be bonded to the metal pad layer 22a or 22b.

As shown in FIG. 2C, the structure after the bonding process may include an interlayer dielectric 21, a metal pad layer 22a, a protective layer 23, and a package lead line 24. The package lead line 24 may be bonded to the metal pad layer 22a. The metal pad layer 22a may have a slanting surface. This structure may reduce the opening area of the metal pad and increase the bonding area.

The above-described metal pad of a semiconductor device and method for bonding the metal pad includes the metal pads of two adjacent chips. Then, FAB-out occurs without having to perform etching and washing processes to open the pad area, and the wafer sawing process is carried out, thereby simplifying the process. Also, by forming the cutting surface at an angle of less than or equal to, for example, about 45° during the sawing process, a maximum bonding area may be obtained within the opening area, thereby increasing the efficiency of the bonding process.

As described above, the metal pad of a semiconductor device and the method for bonding the metal pad according to the present invention may have the following advantages. Because etching and washing processes is not necessary to open a metal pad region, the fabrication process can be simplified, and the metal pad can be substantially free from contamination. Also, since the pad opening process is not necessary, the fabrication cost can be reduced.

Furthermore, the metal pad may be prevented from being contaminated and a maximum bonding area can be ensured within a limited area, thereby enhancing product yields and efficiency of the bonding process. And, finally, a sawing process may be performed when the pad opening process is not in a FAB-in state, thereby allowing a uniform and consistent process to be carried out regardless of the type of device.

It will be apparent to those skilled in the art that various modifications and variations can be made in the present invention without departing from the spirit or scope of the inventions. Thus, it is intended that the present invention covers the modifications and variations of this invention provided they come within the scope of the appended claims and their equivalents.

The present application contains subject matter related to Korean Patent Application No. 10-2004-0058640, filed on Jul. 27, 2004, the entire contents of which being incorporated herein by reference.

What is claimed is:

1. A method of bonding a metal pad of the semiconductor device, comprising steps of:
forming a metal pad in a pad forming area of a chip and another pad forming area of another chip, the another chip being adjacent to the chip and both the chip and the another chip being on a wafer;
forming a protective layer at least on the metal pad;
separating the metal pad to provide separated metal pads, one of the separated metal pads being attached to the chip and another of the separated metal pads being attached to the another chip;
removing at least some of the protective layer and at least some of the one of the separated metal pads to provide an exposed metal pad; and
attaching a package lead line to the exposed metal pad.

2. The method of claim 1, further comprising:
removing at least some of the protective layer and at least some of the another of the separated metal pads to provide another exposed metal pad; and
attaching another package lead line to the another exposed metal pad.

3. The method of claim 1, wherein the separating step includes sawing the wafer.

4. The method of claim 1, wherein the removing step includes cutting at least some of the protective layer and at least some of the one of the separated metal pads so that the exposed metal pad has a slanting surface.

5. The method of claim 4, wherein a slope of the slanting surface is less than or equal to about 45°.

6. A metal pad of a semiconductor device, comprising:
a metal pad layer having an inclined surface at a bonding area being bonded to an interlayer dielectric of a substrate including a plurality of individualized chips; and
a protective layer formed on an entire surface including the metal pad layer except for the bonding area of the metal pad layer,
wherein a package lead line is bonded to the inclined surface of the bonding area of the metal pad layer by using a melted metal.

7. The metal pad of claim 6, wherein a thickness of the inclined surface of the metal pad layer becomes thinner starting from a center portion of the chip to an edge portion of the chip.

8. In a bonding process of a metal pad of a semiconductor device, a method of bonding the metal pad of the semiconductor device, comprising:
forming a non-separated metal pad as a single body in a pad forming area of any one chip on a wafer and a pad forming area of an adjacent chip;
forming a protective layer on an entire surface including the metal pad layer;
forming a separated metal pad layer starting from each chip by separating the non-separated metal pad during a process of individualizing each chip by sawing a wafer being in a FAB-out state; and
bonding the separated metal pad layer to a package lead line in a bonding area of the metal pad layer.

9. The method of claim 8, wherein the non-separated metal pad layer is formed on the any one chip and the adjacent chip starting from a scribe lane, which is used as a cutting part during the process of individualizing each chip.
